(19) United States
(12) Patent Application Publication
(10) Pub. No.: US 2008/0237620 A1
(43) Pub. Date: Oct. 2, 2008

(54) LIGHT EMITTING DIODE APPARATUS

(76) Inventors: Ching-Chuan Shiue, Taoyuan Hsien (TW); Shih-Peng Chen, Taoyuan Hsien (TW); Chao-Min Chen, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 12/029,938

(22) Filed: Feb. 12, 2008

(30) Foreign Application Priority Data
Mar. 30, 2007 (TW) 096111216

(51) Int. Cl. H01L 33/00

(52) U.S. Cl. 257/98; 257/E33.001

(57) ABSTRACT

A light emitting diode apparatus includes a heat dissipating substrate, a composite layer, an epitaxial layer, a first electrode and a second electrode. The composite layer includes a reflective layer, a transparent conductive layer and a patterned insulating thermoconductive layer, which is disposed between the reflective layer and the transparent conductive layer. The composite layer is disposed between the heat dissipating substrate and the epitaxial layer and allows currents to concentrate to the reflective layer or the transparent conductive layer and then to be diffused evenly through the transparent conductive layer. The epitaxial layer includes a first semiconductor layer electrically connected with the first electrode, an active layer and a second semiconductor layer electrically connected with the second electrode.

### CROSS REFERENCE TO RELATED APPLICATIONS

This Non-provisional application claims priority under 35 U.S.C. §19(a) on Patent Application No(s). 096111216 filed in Taiwan, Republic of China on Mar. 30, 2007, the entire contents of which are hereby incorporated by reference.

### BACKGROUND OF THE INVENTION

1. Field of Invention

The invention relates to a light emitting source and, in particular, to a light emitting diode apparatus.

2. Related Art

A light emitting diode (LED), a cold lighting element for releasing energy, generates light when electrons and holes in a semiconductor material are combined together Monochromatic light with different wavelengths can be outputted according to the used material. The LEDs can be mainly classified into a visible light LED and an invisible light (infrared) LED. Compared with the conventional light bulb or lamp, the LED has the advantages of power-saving property, vibration-resistant property and high flickering speed. Thus, the LED has become an indispensable and important element in the daily life.

Referring to FIG. 1, a conventional LED element 10 includes an epitaxial substrate 100, a first semiconductor layer 101, an active layer 102 and a second semiconductor layer 103. The first semiconductor layer 101, the active layer 102 and the second semiconductor layer 103 are in sequence formed on the epitaxial substrate 100. Then, a first electrode 11 is connected to the first semiconductor layer 101 and a second electrode 12 is connected to the second semiconductor layer 103. In the following example, in which the first semiconductor layer 101 is an n-type semiconductor layer and the second semiconductor layer 103 is a p-type semiconductor layer, when a voltage is applied to the semiconductor layers 101 and 103 to generate a current, electrons and holes in the n-type and p-type semiconductor layers are combined so that the active layer 102 emits the light.

In order to achieve the heat-dissipating effect and to enhance the light outputting efficiency, the LED element 10 is typically packaged on a heat dissipating substrate in a flip chip manner, and a reflective layer is formed between the heat dissipating substrate and the LED element 10. The heat dissipating substrate can solve the problem of poor heat dissipating efficiency caused by the conventional epitaxial substrate. The reflective layer reflects the light outputted from the active layer 102 to concentrate the outputted light and thus to emit the concentrated light in the same direction. Thus, the phenomenon of the light loss, which is caused when the light is shielded by the conventional electrodes 11, 12 and the light is outputted toward the epitaxial substrate 100, can be eliminated.

In addition, as shown in FIG. 2, a conventional flip-chip type light emitting diode apparatus 2 further has pillars 204, which are disposed separately and formed on a side of a second semiconductor layer 203. A transparent insulating layer 205 is formed between two adjacent pillars 204, and a reflective layer 206 is formed on the transparent insulating layer 205 and the second semiconductor layer 203. The transparent insulating layers 205, which are disposed separately, can concentrate the currents and thus enhance the opto-electronic conversion efficiency. However, because the reflective layer 206 is usually made of metal materials, the junction between the reflective layer 206 and the second semiconductor layer 203 has the phenomenon of high Schottky barrier. Thus, the resistance value is too high so that the currents cannot be evenly diffused. That is, the current blocking effect is caused in the junction so that the operation voltage of the light emitting diode apparatus 2 rises. In addition, no path can conduct the accumulated heat generated therewith to the outside so that the more serious heat dissipating problem is caused.

Therefore, there is a need to provide a light emitting diode apparatus having evenly diffused currents, good thermal conductivity and high opto-electronic conversion efficiency.

### SUMMARY OF THE INVENTION

An object of the invention is to provide a light emitting diode apparatus having evenly diffused currents, good thermal conductivity and high opto-electronic conversion efficiency.

To achieve the above, the invention discloses a light emitting diode apparatus including a heat dissipating substrate, a composite layer, an epitaxial layer, a first electrode and a second electrode. The composite layer includes a reflective layer, a transparent conductive layer and a patterned insulating thermoconductive layer disposed between the reflective layer and the transparent conductive layer. The composite layer is disposed between the heat dissipating substrate and the epitaxial layer and allows currents to concentrate to the reflective layer or the transparent conductive layer and then to be evenly diffused through the transparent conductive layer. The epitaxial layer includes a first semiconductor layer, an active layer and a second semiconductor layer. The first electrode is electrically connected to the first semiconductor layer. The second electrode is electrically connected to the second semiconductor layer.

As mentioned above, the composite layer, which includes the transparent conductive layer, the patterned insulating thermoconductive layer and the reflective layer, is formed between the epitaxial layer and the heat dissipating substrate in the light emitting diode apparatus according to the invention, so that the currents can concentrate and pass through the composite layer and the currents can be evenly distributed through the transparent conductive layer. In addition, the junction between the transparent conductive layer and the epitaxial layer can provide good Ohmic contact to prevent the conventional phenomenon of current blocking effect effectively. In addition, the high thermal conductivity of the patterned insulating thermoconductive layer can provide the heat dissipating path so that the heat dissipating efficiency of the light emitting diode apparatus can be enhanced more effectively with respect to the prior art.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional LED element;

FIG. 2 is a schematic illustration showing a conventional flip-chip type LED apparatus;

FIGS. 3 to 6 are schematic illustrations showing a light emitting diode apparatus according to an embodiment of the invention; and

FIGS. 7 to 10 are schematic illustrations showing another light emitting diode apparatus according to the embodiment of the invention.

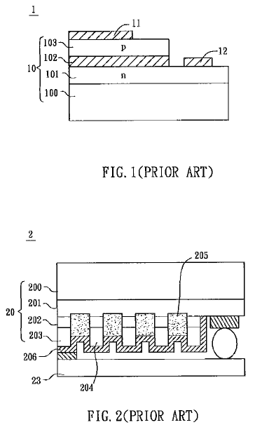

### DETAILED DESCRIPTION OF THE INVENTION

The present invention will be apparent from the following detailed description, which proceeds with reference to the accompanying drawings, wherein the same references relate to the same elements.

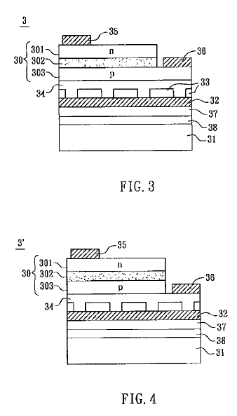

Referring to FIG. 3, a light emitting diode apparatus 3 according to an embodiment of the invention includes a heat dissipating substrate 31, a composite layer S, an epitaxial layer 30, a first electrode 35 and a second electrode 36.

The heat dissipating substrate 31 is a permanent substrate having a high coefficient of heat conductivity, and can be made of a metal material, a composite material or an insulating material. In this embodiment, the material of the heat dissipating substrate 31 can be aluminum, copper, aluminum copper oxide, silicon, gallium arsenide, gallium phosphide, silicon carbide, boron nitride, aluminum nitride, a ceramic material or any combination thereof.

The composite layer S includes a reflective layer 32, a transparent conductive layer 34 and a patterned insulating thermoconductive layer 33 disposed between the reflective layer 32 and the transparent conductive layer 34. In this embodiment, the material of the reflective layer 32 is metal, such as platinum (Pt), gold (Au), silver (Ag), palladium (Pd), aluminum (Al), titanium (Ti), iridium (Ir) or rhodium (Rh).

The patterned insulating thermoconductive layer 33 is disposed on the reflective layer 32 and is a patterned layer having patterns arranged separately. The intervals between adjacent patterns of the patterned insulating thermoconductive layer 33 can be the same or different from one another. Because the bandgap of aluminum nitride (AlN) is about 6.2 electron volts (eV), the aluminum nitride (AlN) is light-permeable under the condition of the UV light having the wavelength of about 360 nm. Thus, the patterned insulating thermoconductive layer 33 in this embodiment is light-permeable and has high thermal conductivity. The material of the patterned insulating thermoconductive layer 33 may be silicon carbide (SiC) or aluminum nitride (AlN).

As shown in FIG. 3, the transparent conductive layer 34 is disposed on the patterned insulating thermoconductive layer 33 and the reflective layer 32, and a junction between a second semiconductor layer 303 and the reflective layer 32 is formed with the Ohmic contact so that the contact resistance can be decreased. In this embodiment, the material of the transparent conductive layer 34 can be a transparent conductive material, such as nickel (Ni), gold (Au) or indium tin oxide (ITO).

As shown in FIG. 3, the epitaxial layer 30 is disposed on the transparent conductive layer 34, and the epitaxial layer 30 in sequence includes a first semiconductor layer 301, an active layer 302 and the second semiconductor layer 303. The second semiconductor layer 303, the active layer 302 and the first semiconductor layer 301 are in sequence formed on the transparent conductive layer 34. In this embodiment, the first semiconductor layer 301 can be an n-type semiconductor layer, and the second semiconductor layer 303 can be a p-type semiconductor layer. Of course, the first semiconductor layer 301 and the second semiconductor layer 303 can be respectively the p-type semiconductor layer and the n-type semiconductor layer according to the actual requirement.

The first electrode 35 is electrically connected to the first semiconductor layer 301, and the second electrode 36 is electrically connected to the second semiconductor layer 303. Detailed descriptions will be made according to the example, in which the first electrode 35 and the second electrode 36 are disposed at the same side of the heat dissipating substrate 31 to form a front-side light emitting diode apparatus. As shown in FIG. 3, the first electrode 35 is formed on the first semiconductor layer 301, and the second electrode 36 is formed on the second semiconductor layer 303. It is to be specified that the relative position of each layer is defined according to FIG. 3, and the layers are not limited to be formed by stacking from bottom to top. Furthermore, a non-conductive substrate is illustrated in this embodiment. Of course, a conductive substrate can be adopted as long as an insulating layer is additionally added to the conductive substrate.

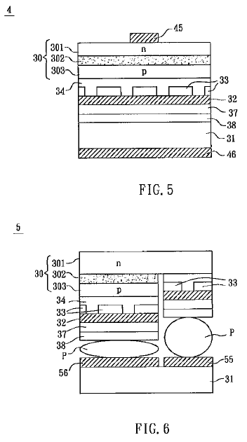

In addition, as shown in FIG. 4, the second semiconductor layer 303 can be etched to expose a portion of the transparent conductive layer 34 according to the actual requirement so that the second electrode 36 is formed on the exposed transparent conductive layer 34. According to the positions of the first electrode and the second electrode, a first electrode 45 and a second electrode 46 can also be respectively disposed oil opposite side surfaces of the heat dissipating substrate 31 to form a vertical light emitting diode apparatus 4, as shown in FIG. 5. Herein, the first electrode 45 is formed on the first semiconductor layer 301, and the second electrode 46 is formed on a bottom surface of the heat dissipating substrate 31.

As shown in FIG. 6, the epitaxial layer 30 is connected with a first electrode 55 and a second electrode 56 in a flip chip manner to form a flip-chip type light emitting diode apparatus 5. Herein, the first electrode 55 and the second electrode 56 are disposed on the heat dissipating substrate 31, and are then electrically connected to the first semiconductor layer 301 and the second semiconductor layer 303 through bonding pads P, respectively.

When the first electrodes 35, 45 and 55 and the second electrodes 36, 46 and 56 apply voltages to the first semiconductor layer 301 and the second semiconductor layer 303 to generate currents, respectively, the patterned insulating thermoconductive layer 33 can force the currents to concentrate to the transparent conductive layer 34 and then to be evenly diffused through the transparent conductive layer 34. Thus, the electrons and the holes of the first semiconductor layer 301 and the second semiconductor layer 303 are combined in the active layer 302, and the energy released when the electrons and the holes are combined is finally converted into the light.

In addition, the patterned insulating thermoconductive layer 33 having high thermal conductivity can provide a good path for conducting the heat to the heat dissipating substrate 31 so that the operating temperature of the light emitting diode apparatuses 3, 4 and 5 can be effectively lowered.

Furthermore, as shown in FIGS. 3 to 6, each of the light emitting diode apparatuses 3, 4, 5 of this embodiment preferably includes a barrier layer 37, which is disposed between the heat dissipating substrate 31 and the reflective layer 32 and is for blocking other metal ions from being diffused into the reflective layer 32. In this embodiment, the material of the barrier layer 37 is nickel, titanium, platinum, palladium, iridium, rhodium, chromium or any combination thereof.

Also, each of the light emitting diode apparatuses 3, 4, 5 of this embodiment further includes an adhesive layer 38, which is disposed between the reflective layer 32 and the heat dissipating substrate 31, and especially disposed between the barrier layer 37 and the heat dissipating substrate 31. The adhesive layer 38 connects the epitaxial layer 30 to the heat dissipating substrate 31, and the material of the adhesive layer 38 can be a silver paste, a solder paste or a solder-silver paste. The adhesive layer 38 is firstly formed on one side of the barrier layer 37, and then the adhesive layer 38 is connected to the barrier layer 37 and the heat dissipating substrate 31.

FIG. 7 shows another light emitting diode apparatus 6. What is different from the above-mentioned light emitting diode apparatuses 3, 4 or 5 is that a reflective layer 32a has a concave-convex surface, a patterned insulating thermoconductive layer 33a is filled in the concave portion or the sidewall of the reflective layer 32a, and a transparent conductive layer 34a is formed over the patterned insulating thermoconductive layer 33a and the reflective layer 32a. Thus, the objects of evenly diffusing the currents, enhancing the heat dissipating effect and enhancing the opto-electronic conversion can be achieved.

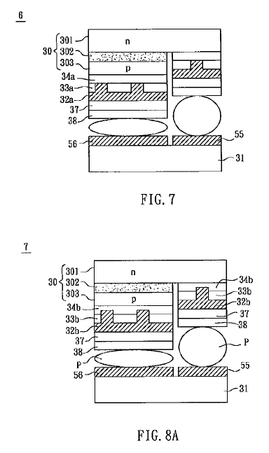

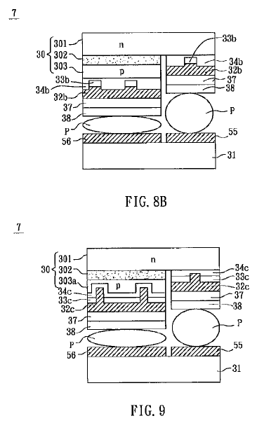

Also, the patterned insulating thermoconductive layer and the transparent conductive layer can be formed on the concave-convex surface of the reflective layer, and the transparent conductive layer is formed over the patterned insulating thermoconductive layer and the reflective layer. As shown in FIG. 8A, a patterned insulating thermoconductive layer 33b is formed in a portion of a concave portion of a concave-convex surface of a reflective layer 32b, and a transparent conductive layer 34b is formed over the patterned insulating thermoconductive layer 33b and the reflective layer 32b, and a portion of the transparent conductive layer 34b are formed in the concave portion of the reflective layer 32b. Alternatively, as shown in FIG. 8B, the patterned insulating thermoconductive layer 33b is disposed on a convex portion of the reflective layer 32b, and the transparent conductive layer 34b covers the patterned insulating thermoconductive layer 33b and the reflective layer 32b. As shown in FIGS. 8A and 8B, in the light emitting diode apparatus 7, the transparent conductive layer 34b includes a concave portion corresponding to the convex portion of the reflective layer 32b, and a convex portion corresponding to the concave portion of the reflective layer 32b.

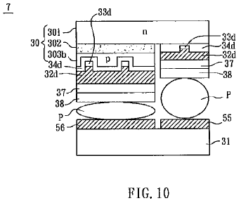

In addition, the concave-convex surface of the reflective layer can also be filled by the patterned insulating thermoconductive layer, the transparent conductive layer and the second semiconductor layer. As shown in FIG. 9, a convex portion of a concave-convex surface of a reflective layer 32c can also be filled by a patterned insulated thermoconductive layer 330, a transparent conductive layer 34c and a second semiconductor layer 303a. Herein, the transparent conductive layer 34c covers the patterned insulated thermoconductive layer 33c and the reflective layer 32c. The effect can be achieved by etching the second semiconductor layer 303a. However, the invention is not limited thereto. For example, the reflective layer can be filled on the patterned insulating thermoconductive layer, the transparent conductive layer, the second semiconductor layer, the active layer and the concave-convex surface of the first semiconductor layer by further etching the active layer and the first semiconductor layer.

Furthermore, as shown in FIG. 10, a patterned insulating thermoconductive layer 33d can also be disposed on a convex portion of a concave-convex surface of a reflective layer 32d, and then a transparent conductive layer 34d covers the patterned insulating thermoconductive layer 33d and the reflective layer 32d. Herein, this effect is achieved by etching a portion of a second semiconductor layer 303b.

As shown in FIGS. 9 and 10, in the light emitting diode apparatus 7, the second semiconductor layer 303b includes a concave portion corresponding to the convex portion of the reflective layer 32b, and a convex portion corresponding to the concave portion of the reflective layer 32b.

As mentioned hereinabove, the composite layer having the reflective layer, the patterned insulating thermoconductive layer and the transparent conductive layer can also be applied to the front-side light emitting diode apparatus, the vertical light emitting diode apparatus or the flip-chip type light emitting diode apparatus.

In summary the composite layer, which includes the transparent conductive layer, the patterned insulating thermoconductive layer and the reflective layer, is formed between the epitaxial layer and the heat dissipating substrate in the light emitting diode apparatus according to the invention, so that the currents can concentrate and pass through the composite layer and the currents can be evenly distributed through the transparent conductive layer. In addition, the junction between the transparent conductive layer and the epitaxial layer can provide good Ohmic contact to prevent the conventional phenomenon of current blocking effect effectively. In addition, the high thermal conductivity of the patterned insulating thermoconductive layer can provide the heat dissipating path so that the heat dissipating efficiency of the light emitting diode apparatus can be enhanced more effectively with respect to the prior art.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting diode apparatus comprising:
a heat dissipating substrate;
a composite layer comprising a reflective layer, a transparent conductive layer and a patterned insulated thermoconductive layer disposed between the reflective layer and the transparent conductive layer; and
an epitaxial layer comprising a first semiconductor layer, an active layer and a second semiconductor layer;
wherein the composite layer is disposed between the heat dissipating substrate and the epitaxial layer for allowing currents to concentrate to the reflective layer or the transparent conductive layer to be evenly diffused through the transparent conductive layer.

2. The light emitting diode apparatus according to claim 1, further comprising:
a first electrode electrically connected to the first semiconductor layer; and
a second electrode electrically connected to the second semiconductor layer.

3. The light emitting diode apparatus according to claim 1, wherein the reflective layer has a concave-convex surface comprising a convex portion and a concave portion.

4. The light emitting diode apparatus according to claim 3, wherein the patterned insulating thermoconductive layer is disposed on the convex portion of the reflective layer.

5. The light emitting diode apparatus according to claim 4, wherein the transparent conductive layer has a concave portion corresponding to the convex portion of the reflective layer, and a convex portion corresponding to the concave portion of the reflective layer.

6. The light emitting diode apparatus according to claim 4, wherein the transparent conductive layer is formed in the concave portion of the reflective layer and the patterned insulating thermoconductive layer.

7. The light emitting diode apparatus according to claim 6, wherein the second semiconductor layer contacting the transparent conductive layer has a concave portion corresponding to the convex portion of the reflective layer, and a convex portion corresponding to the concave portion of the reflective layer.

8. The light emitting diode apparatus according to claim 3, wherein the patterned insulating thermoconductive layer is formed in the concave portion of the reflective layer or a sidewall of the reflective layer.

9. The light emitting diode apparatus according to claim 8, wherein the transparent conductive layer is formed on the convex portion of the reflective layer and the patterned insulating thermoconductive layer.

10. The light emitting diode apparatus according to claim 9, wherein the second semiconductor layer contacting the transparent conductive layer has a concave portion corresponding to the convex portion of the reflective layer, and a convex portion corresponding to the concave portion of the reflective layer.

11. The light emitting diode apparatus according to claim 1, wherein the patterned insulating thermoconductive layer has a plurality of patterns arranged separately.

12. The light emitting diode apparatus according to claim 11, wherein intervals between adjacent two of the patterns of the patterned insulating thermoconductive layer are the same or different from one another.

13. The light emitting diode apparatus according to claim 1, wherein a material of the patterned insulating thermoconductive layer is aluminum nitride (AlN) or silicon carbide (SiC).

14. The light emitting diode apparatus according to claim 1, wherein a material of the reflective layer is platinum (Pt), gold (Au), silver (Ag), palladium (Pd), aluminum (Al), titanium (Ti), iridium (Ir), rhodium (Rh) or combinations thereof.

15. The light emitting diode apparatus according to claim 1, wherein a material of the transparent conductive layer is nickel (Ni), gold (Au), indium tin oxide (ITO) or combinations thereof.

16. The light emitting diode apparatus according to claim 1, wherein the heat dissipating substrate is made of a metal material, a composite material or an insulating material.

17. The light emitting diode apparatus according to claim 1, wherein a material of the heat dissipating substrate is aluminum, copper, aluminum copper oxide, silicon, gallium arsenide, gallium phosphide, silicon carbide, boron nitride, aluminum nitride, a ceramic material or combinations thereof.

18. The light emitting diode apparatus according to claim 1, further comprising a barrier layer disposed between the heat dissipating substrate and the composite layer, wherein a material of the barrier layer is nickel, titanium, platinum, palladium, iridium, rhodium, chromium or combinations thereof.

19. The light emitting diode apparatus according to claim 1, further comprising an adhesive layer disposed between the heat dissipating substrate and the composite layer, wherein a material of the adhesive layer is a silver paste, a solder paste or a solder-silver paste, and a material of the adhesive layer comprises lead and lead-free adhesive materials.

20. The light emitting diode apparatus according to claim 1, being applied to a vertical light emitting diode apparatus.

21. The light emitting diode apparatus according to claim 2, wherein the first electrode and the second electrode are disposed on two opposite side of the heat dissipating substrate.

22. The light emitting diode apparatus according to claim 2, being applied to a front-side light emitting diode apparatus or a flip-chip type light emitting diode apparatus.

23. The light emitting diode apparatus according to claim 2, wherein the first electrode and the second electrode are disposed on a side surface of the heat dissipating substrate.
